(19) United States
(12) Patent Application Publication
(10) Pub. No.: US 2024/0344978 A1
(43) Pub. Date: Oct. 17, 2024

(54) TERAHERTZ DETECTION DEVICE

(71) Applicant: SONY SEMICONDUCTOR SOLUTIONS CORPORATION, KANAGAWA (JP)

(72) Inventor: MITSUNARI HOSHI, KANAGAWA (JP)

(21) Appl. No.: 18/579,600

(22) PCT Filed: Mar. 2, 2022
(86) PCT No.: PCT/JP2022/008797

§ 371 Date: Jan. 16, 2024

(30) Foreign Application Priority Data
Aug. 5, 2021 (JP) 2021-129166

(51) Int. Cl. G01N 21/3581; G01N 21/3504

(52) U.S. Cl. CPC G01N 21/3581; G01N 21/3504; G01N 2201/06113

(57) ABSTRACT

To provide a terahertz (THz) detection device that can improve sensitivity for detecting a THz wave. The THz detection device includes: a structure array including a plurality of structures and transmitting the THz wave incident on the structures; an absorption layer that absorbs the THz wave transmitted through the structure array and generates heat and far-infrared light; and a thermoelectric element that converts the heat generated from the absorption layer into electricity, in which the structure array reflects the far-infrared light generated from the absorption layer and incident on the structures, and the absorption layer absorbs the far-infrared light reflected by the structure array.

### TECHNICAL FIELD

The present disclosure relates to a terahertz (THz) detection device.

### BACKGROUND ART

In recent years, electromagnetic wave detection devices that detect various types of electromagnetic waves have been developed. For example, development of a THz detection device including an absorption layer that absorbs a THz wave and generates heat and a thermoelectric element that converts a temperature difference generated by the heat into an electromotive current has been energetically conducted.

### CITATION LIST

### Patent Document

Patent Document 1: Japanese Unexamined Patent Application Publication No. 2013-530386
Patent Document 2: Japanese Patent Application Laid-Open No. 2018-040791

### SUMMARY OF THE INVENTION

### Problems to be Solved by the Invention

In development of the THz detection device, it is often required to improve sensitivity for detecting the THz wave. For example, in a case where the THz detection device includes a pixel array including a plurality of pixels for detecting the THz wave, in order to reduce the size of each pixel, the sensitivity of each pixel needs to be improved.

However, in the THz detection device, there is a possibility that a part of thermal energy generated in the absorption layer is radiated to the outside of the absorption layer by radiation of far-infrared light from the absorption layer. In this case, the radiated energy is wasted, and the sensitivity of the THz detection device decreases.

Therefore, the present disclosure provides a THz detection device that can improve sensitivity for detecting the THz wave.

### Solutions to Problems

A THz detection device according to a first aspect of the present disclosure includes: a structure array including a plurality of structures and transmitting a terahertz (THz) wave incident on the structures; an absorption layer that absorbs the THz wave transmitted through the structure array and generates heat and far-infrared light; and a thermoelectric element that converts the heat generated from the absorption layer into electricity, in which the structure array reflects the far-infrared light generated from the absorption layer and incident on the structures, and the absorption layer absorbs the far-infrared light reflected by the structure array. With this arrangement, for example, by causing the absorption layer to absorb the far-infrared light generated from the absorption layer again, the sensitivity for detecting the THz wave can be improved.

Furthermore, in this first aspect, each of the structures may include a material in which a real part of a complex dielectric constant is negative. This enables, for example, to realize a structure array that can reflect the far-infrared light due to the material of the structure.

Furthermore, in this first aspect, the material included in each of the structures may be metal. This enables, for example, the real part of the complex dielectric constant of the material included in the structure to be set negative.

Furthermore, in this first aspect, each of the structures may have a shape that is circular in plan view. This enables, for example, the shape of each structure to have a cylindrical shape, and a structure that can be easily arranged in an array to be realized.

Furthermore, in this first aspect, each of the structures may have a width of 5 μm to 25 μm in plan view. This enables, for example, a structure array in which the far-infrared light is easily reflected to be realized.

Furthermore, in this first aspect, the structures may have a pitch of 5 μm to 25 μm in plan view between the structures. This enables, for example, a structure array in which the far-infrared light is easily reflected to be realized.

Furthermore, in this first aspect, each of the structures may have a thickness of 0.05 μm to 0.5 μm. This enables, for example, a structure array in which the far-infrared light is easily reflected to be realized.

Furthermore, in this first aspect, the structures may be arranged in a two-dimensional array. This enables, for example, to easily realize a structure array that transmits the THz wave and reflects the far-infrared light.

Furthermore, in the first aspect, each of the structures may be provided at a position separated from the absorption layer. This enables, for example, the absorption layer and the structure to be provided on separate substrates.

Furthermore, in this first aspect, each of the structures may be provided at a position in contact with the absorption layer. This enables, for example, the absorption layer and the structure to be provided on the same substrate.

Furthermore, in this first aspect, each of the structures may be provided on a lower surface of a substrate positioned above the absorption layer. This enables, for example, the structure to be provided on a surface on the absorption layer side of the substrate.

Furthermore, in this first aspect, each of the structures may be provided on an upper surface of the substrate positioned above the absorption layer. This enables, for example, the structure to be provided on a surface on the opposite side to the absorption layer side of the substrate.

Furthermore, in this first aspect, each of the structures may be provided on an upper surface of the absorption layer. This enables, for example, the far-infrared light to be reflected on the upper surface of the absorption layer.

Furthermore, in this first aspect, each of the structures may be provided at on a lower surface of the absorption layer. This enables, for example, the far-infrared light to be reflected on the lower surface of the absorption layer.

Furthermore, the THz detection device of the first aspect may further include a reflective layer that is provided on the lower surface of the absorption layer and reflects the far-infrared light generated from the absorption layer to the absorption layer. As a result, for example, the far-infrared light generated from the absorption layer can be reflected by both the structure array and the reflective layer.

Furthermore, in this first aspect, the reflective layer may include a metal layer. This enables, for example, a reflection function of the reflective layer to be realized by metal.

Furthermore, in this first aspect, the absorption layer may include carbon. This enables, for example, an absorption function of the absorption layer to be realized by a layer containing carbon.

Furthermore, in this first aspect, the absorption layer may include a carbon nanotube, graphene, or graphite. This enables, for example, an absorption layer in which the THz wave is easily absorbed to be realized.

Furthermore, in this first aspect, the thermoelectric element may include one or more n-type semiconductor layers and one or more p-type semiconductor layers electrically insulated from the absorption layer. This enables, for example, the thermoelectric element to be realized with a simple structure.

Furthermore, in this first aspect, the one or more n-type semiconductor layers and the one or more p-type semiconductor layers may be electrically connected to each other in series. This enables, for example, the potential difference obtained by the thermoelectric element to be increased by increasing the number of these semiconductor layers.

### BRIEF DESCRIPTION OF DRAWINGS

FIG. 1 is a cross-sectional view illustrating a structure of a THz detection device according to a first embodiment.

FIG. 2 is a plan view illustrating a structure of the THz detection device according to the first embodiment.

FIG. 3 is a perspective view and a plan view illustrating a structure of a structure array according to the first embodiment.

FIG. 4 is a graph for explaining characteristics of the THz detection device according to the first embodiment.

FIG. 5 is a cross-sectional view for describing a problem of the THz detection device according to a first comparative example of the first embodiment.

FIG. 6 is a cross-sectional view illustrating a structure of a THz detection device according to a second embodiment.

FIG. 7 is a cross-sectional view illustrating a structure of a THz detection device according to a third embodiment.

FIG. 8 is a cross-sectional view illustrating a structure of a THz detection device according to a fourth embodiment.

FIG. 9 is a cross-sectional view illustrating a structure of a THz detection device according to a fifth embodiment.

FIG. 10 is a graph for explaining characteristics of the THz detection devices according to the first to fifth embodiments and the like.

FIG. 11 is a block diagram illustrating a configuration example of an electronic device.

FIG. 12 is a block diagram illustrating a configuration example of a mobile body control system.

FIG. 13 is a plan view illustrating a specific example of a setting position of an imaging unit in FIG. 12.

FIG. 14 is a diagram illustrating an example of a schematic configuration of an endoscopic surgery system.

FIG. 15 is a block diagram illustrating an example of a functional configuration of a camera head and a camera control unit (CCU).

### MODE FOR CARRYING OUT THE INVENTION

Hereinafter, embodiments of the present disclosure are described below with reference to the drawings.

### First Embodiment

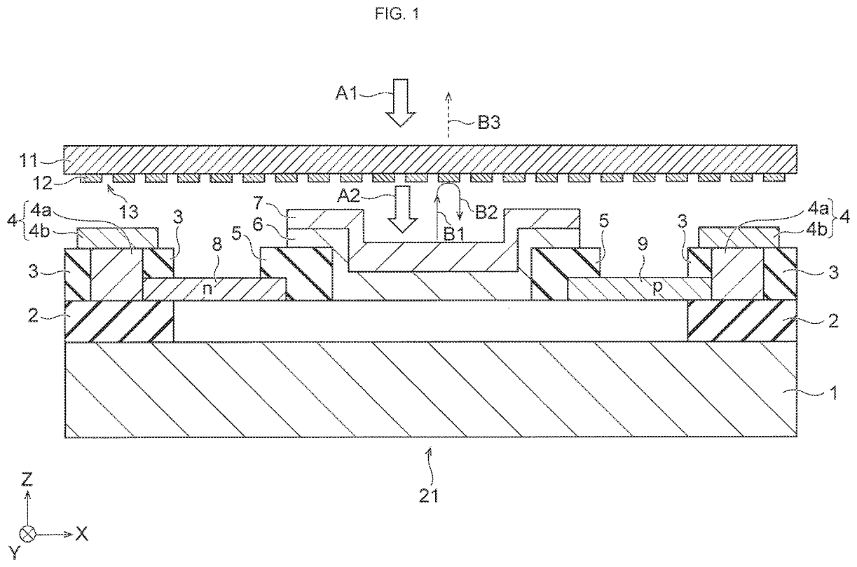

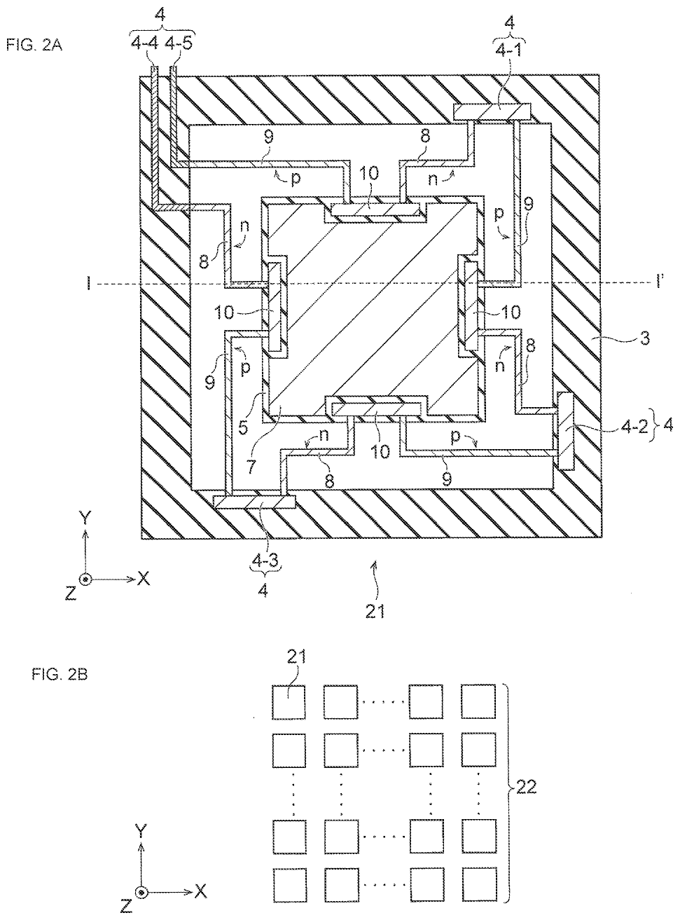

FIG. 1 is a cross-sectional view illustrating a structure of a THz detection device according to a first embodiment. FIG. 2 is a plan view illustrating a structure of the THz detection device according to the first embodiment.

As illustrated in FIG. 1, the THz detection device according to the present embodiment includes a substrate 1, a lower insulating film 2, an upper insulating film 3, a plurality of wiring lines 4, an insulating film 5, a reflective layer 6, an absorption layer 7, a plurality of n-type semiconductor layers 8, a plurality of p-type semiconductor layers 9, a substrate 11, and a plurality of structures 12. FIG. 1 illustrates one of the plurality of n-type semiconductor layers 8 and one of the plurality of p-type semiconductor layers 9. Furthermore, the plurality of structures 12 is arranged in an array on one surface of the substrate 11 to form a structure array 13.

FIG. 1 illustrates an X axis, a Y axis, and a Z axis perpendicular to each other. An X direction and a Y direction correspond to a lateral direction (horizontal direction), and a Z direction corresponds to a longitudinal direction (vertical direction). Furthermore, the +Z direction corresponds to an upward direction, and the −Z direction corresponds to a downward direction. The −Z direction may strictly match the gravity direction, or may not strictly match the gravity direction.

FIG. 1 illustrates a cross section of one pixel 21 included in the THz detection device according to the present embodiment. A of FIG. 2 illustrates a planar structure of the pixel 21. A of FIG. 2 illustrates the plurality of n-type semiconductor layers 8 described above, the plurality of p-type semiconductor layers 9 described above, the plurality of wiring lines 10, and the like included in the pixel 21. FIG. 1 illustrates a cross section taken along a line I-I′ in A of FIG. 2. However, in FIG. 1, the wiring line 4 not disposed on the line I-I′ is illustrated for easy understanding of the description, and conversely, a wiring line 10 disposed on the line I-I′ is not illustrated. Furthermore, B of FIG. 2 schematically illustrates a planar structure of a pixel array 22 in the THz detection device according to the present embodiment. The pixel array 22 includes a plurality of the pixels 21, and each pixel 21 has a structure illustrated in FIG. 1 and A of FIG. 2.

Hereinafter, the structure of the THz detection device according to the present embodiment is described with reference to FIG. 1. In this description, reference is also made to A and B of FIG. 2 as necessary.

The substrate 1 is, for example, a semiconductor substrate such as a silicon substrate, an insulating substrate such as a glass substrate or a ceramic substrate, or a metal substrate such as an aluminum substrate. The lower insulating film 2 is formed on the substrate 1. The lower insulating film 2 is, for example, a silicon oxide film (SiO₂). The upper insulating film 3 is formed on the lower insulating film 2. The upper insulating film 3 is, for example, a silicon nitride film (SiN). In the present embodiment, the lower insulating film 2 and the upper insulating film 3 in each pixel 21 have a quadrangular annular shape in plan view (see A of FIG. 2). The lower insulating film 2 and the upper insulating film 3 include different insulating materials in the present embodiment, but may include the same insulating material.

Each wiring line 4 includes a lower wiring layer 4a formed in the lower insulating film 3 and an upper wiring layer 4b formed on the lower insulating film 3 and the lower wiring layer 4a. The lower wiring layer 4a and the upper wiring layer 4b may include different materials, or may include the same material. The lower wiring layer 4a is, for example, a metal conductive layer such as an aluminum (Al) layer, a copper (Cu) layer, or a tungsten (W) layer. Similarly, the upper wiring layer 4b is, for example, a metal conductive layer such as an Al layer, a Cu layer, or a W layer. Note that each wiring line 4 may include only the lower wiring layer 4a, and may not include the upper wiring layer 4b.

The insulating film 5, the reflective layer 6, and the absorption layer 7 are formed in order above the substrate 1. The insulating film 5, the reflective layer 6, and the absorption layer 7 are accommodated on the inner side of the ring formed by the lower insulating film 2 and the upper insulating film 3 (see A of FIG. 2). The reflective layer 6 is formed on the upper surface and the side surface of the insulating film 5, and has an inner upper surface, an outer upper surface, and a side surface between these upper surfaces. The absorption layer 7 is formed on the upper surface and the side surface of the reflective layer 6, and has an inner upper surface, an outer upper surface, and a side surface between these upper surfaces, similarly to the reflective layer 6. In the present embodiment, a cavity exists between the upper surface of the substrate 1 and the lower surfaces of the insulating film 5 and the reflective layer 6. This cavity may be vacuum or filled with air or other gas.

The insulating film 5 is, for example, a silicon nitride film. In the present embodiment, the upper insulating film 3 and the insulating film 5 may be formed by forming one silicon nitride film above the substrate 1 and dividing the silicon nitride film into the upper insulating film 3 and the insulating film 5.

The reflective layer 6 has a function of reflecting electromagnetic waves such as far-infrared light. The reflective layer 6 is, for example, a metal layer such as an Al layer, and this allows the reflective function described above to be realized. In the present embodiment, the upper wiring layer 4b and the reflective layer 6 may be formed by forming one metal layer above the substrate 1 and dividing the metal layer into the upper wiring layer 4b and the reflective layer 6. Further details of the reflective layer 6 will be described later.

The absorption layer 7 has a function of absorbing electromagnetic waves such as a THz wave and far-infrared light. The absorption layer 7 is, for example, a layer containing carbon in the form of carbon nanotubes, graphene, graphite, or the like, and this allows the absorption function described above to be realized. Further details of the absorption layer 7 will be described later.

The n-type semiconductor layer 8 and the p-type semiconductor layer 9 are formed above the substrate 1. In the present embodiment, the cavity exists between the upper surface of the substrate 1 and the lower surfaces of the n-type semiconductor layer 8 and the p-type semiconductor layer 9. As described above, this cavity may be vacuum or filled with air or other gas.

Each n-type semiconductor layer 8 has one end electrically connected to the wiring line 4 on the upper insulating film 3 side and the other end electrically connected to the wiring line 10 on the insulating film 5 side, and extends linearly between these ends (see A of FIG. 2). Similarly, each p-type semiconductor layer 9 has one end electrically connected to the wiring line 4 on the upper insulating film 3 side and the other end electrically connected to the wiring line 10 on the insulating film 5 side, and extends linearly between these ends (see A of FIG. 2). The n-type semiconductor layer 8, the p-type semiconductor layer 9, and the wiring line 10 according to the present embodiment are electrically insulated from the reflective layer 6 and the absorption layer 7 by the insulating film 5. Each wiring line 10 includes, for example, a metal conductive layer such as an Al layer, a Cu layer, or a W layer.

Each n-type semiconductor layer 8 is, for example, a polycrystalline silicon (Si) layer or a polycrystalline silicon germanium (SiGe) layer containing n-type impurities, and thus can function as a thermoelectric element that converts heat into electricity. Similarly, each p-type semiconductor layer 9 is, for example, a polycrystalline Si layer or a polycrystalline SiGe layer containing p-type impurities, and thus can function as a thermoelectric element that converts heat into electricity. Therefore, each pixel 21 according to the present embodiment includes four thermoelectric elements including the four n-type semiconductor layers 8 and four thermoelectric elements including the four p-type semiconductor layers 9 (see A of FIG. 2). In the present embodiment, when the absorption layer 7 absorbs the THz wave and generates heat, each thermoelectric element converts a temperature difference generated by the heat into an electromotive current by the Seebeck effect. Note that, in the n-type semiconductor layer 8, an electromotive current flows from the low temperature side to the high temperature side, and in the p-type semiconductor layer 9, an electromotive current flows from the high temperature side to the low temperature side.

In each pixel 21 according to the present embodiment, the n-type semiconductor layer 8 and the p-type semiconductor layer 9 are electrically connected in series to each other via the three wiring lines 4 (wiring lines 4-1, 4-2, 4-3) and the four wiring lines 10 (see A of FIG. 2). Therefore, in a case where the potential difference generated by one thermoelectric element is represented by ΔV, each pixel 21 can generate a potential difference of 8ΔV by the eight thermoelectric elements. In a case where the number of thermoelectric elements in each pixel 21 is represented by N, if N is too small, the potential difference “NΔV” does not become sufficiently large, and if N is too large, each thermoelectric element cannot receive sufficient heat. Therefore, the value of N in the present embodiment is set to 8, which is a value that is neither too small nor too large.

In the pixel array 22 illustrated in B of FIG. 2, each pixel 21 outputs a signal based on this potential difference to the outside through the two wiring lines 4 (wiring lines 4-4, 4-5) illustrated in A of FIG. 2. The THz detection device according to the present embodiment can detect the THz wave using this signal. The wiring line 4-4 is in contact with the n-type semiconductor layer 8 that is not in contact with the wiring lines 4-1, 4-2, and 4-3, and the wiring line 4-5 is in contact with the p-type semiconductor layer 9 that is not in contact with the wiring lines 4-1, 4-2, and 4-3. Therefore, the four n-type semiconductor layers 8 and the four p-type semiconductor layers 9 illustrated in A of FIG. 2 are electrically connected in series to each other between the wiring line 4-4 and the wiring line 4-5. The wiring lines 4-4 and 4-5 are used as external extraction wiring lines for extracting the electromotive current generated in each pixel 1 to the outside.

The substrate 11 is disposed above the substrate 1. The substrate 11 is, for example, a transparent substrate such as a glass substrate. In the present embodiment, a space between the substrate 1 and the substrate 11 may be a vacuum, or may be filled with air or other gas. However, in order to make heat of the absorption layer 7, the n-type semiconductor layer 8, and the p-type semiconductor layer 9 difficult to escape, it is desirable that this space and the above-described cavity are in a vacuum state or in a reduced pressure state containing a gas other than air. In this case, moreover, the substrate 11 is desirably a window material of a package material. The substrates 1 and 11 according to the present embodiment are both fixed to some constituents in the THz detection device such that the interval between the substrate 1 and the substrate 11 is constant.

In the present embodiment, each structure 12 is provided on the lower surface of the substrate 11. Each structure 12 is a protrusion protruding in the −Z direction from the lower surface of the substrate 11, and the structures 12 are separated from each other in the lateral direction. Therefore, the structures 12 according to the present embodiment are not in contact with each other. These structures 12 are arranged in a two-dimensional array on the lower surface of the substrate 11 to form the structure array 13. Furthermore, in the present embodiment, these structures 12 are separated from the substrate 1, the reflective layer 6, the absorption layer 7, and the like, and are not in contact with the substrate 1, the reflective layer 6, the absorption layer 7, and the like.

The structure array 13 is designed to transmit the THz wave incident on these structures 12. In FIG. 1, the THz wave incident on the structure array 13 is indicated by an arrow A1, and the THz wave transmitted through the structure array 13 is indicated by an arrow A2. The THz wave transmitted through the structure array 13 is incident on the upper surface of the absorption layer 7. The absorption layer 7 absorbs the THz wave and generates heat. The n-type semiconductor layer 8 and the p-type semiconductor layer 9 convert a temperature difference generated by this heat into an electromotive current. Each pixel 21 generates a potential difference by the n-type semiconductor layer 8 and the p-type semiconductor layer 9, and outputs a signal based on the potential difference to the outside. The THz detection device according to the present embodiment can detect the THz wave using this signal.

It is known that the THz wave is generated from, for example, a human body. When the THz wave generated from the human body is incident on each pixel 21, the THz wave is transmitted through the substrate 11 and the structure array 13 and is incident on the absorption layer 7 of each pixel 21. As a result, the THz wave is detected. The THz detection device according to the present embodiment can detect various types of information regarding a human being to be detected by detecting such a THz wave by the plurality of pixels 21. Note that the THz detection device according to the present embodiment may be used to detect a THz wave other than the THz wave generated from the human body.

Next, the far-infrared light generated from the absorption layer 7 is described with continued reference to FIG. 1.

The absorption layer 7 that has absorbed the THz wave may not only generate heat but also generate the far-infrared light. Therefore, there is a possibility that a part of thermal energy generated in the absorption layer 7 is radiated to the outside of the absorption layer 7 by radiation of the far-infrared light from the absorption layer 7. In this case, the radiated energy is wasted to cause the sensitivity of the THz detection device to decrease.

Therefore, the structure array 13 according to the present embodiment is designed to reflect the far-infrared light incident on these structures 12. In FIG. 1, the far-infrared light generated from the absorption layer 7 and incident on the structure array 13 is indicated by an arrow B1, and the far-infrared light reflected by the structure array 13 is indicated by an arrow B2. All or most of the far-infrared light incident on the structure array 13 according to the present embodiment is reflected by the structure array 13 and none or a little of the far-infrared light is transmitted through the structure array 13. An arrow B3 schematically illustrates the above fact.

The far-infrared light reflected by the structure array 13 is incident again on the upper surface of the absorption layer 7. The absorption layer 7 according to the present embodiment absorbs this far-infrared light and generates heat. The heat from the absorption layer 7 that has absorbed the far-infrared light is used for thermoelectric conversion by the n-type semiconductor layer 8 and the p-type semiconductor layer 9, similarly to the heat from the absorption layer 7 that has absorbed the THz wave. With this arrangement, the waste of energy described above can be suppressed and the sensitivity of the THz detection device can be improved.

Each structure 12 according to the present embodiment includes a material (for example, metal) in which the real part of the complex dielectric constant is negative. Examples of the metal include aluminum (Al), tungsten (W), and silver (Ag). The function of the structure array 13 reflecting the far-infrared light can be realized, for example, by forming each structure 12 with such a material. In the present embodiment, each structure 12 includes a material having a large absolute value of the real part of the complex dielectric constant, so that the function of the structure array 13 reflecting the far-infrared light can be improved.

The THz detection device according to the present embodiment includes the structure array 13 above the absorption layer 7 and the reflective layer 6 on the lower surface of the absorption layer 7. Therefore, the far-infrared light emitted upward from the absorption layer 7 can be reflected by the structure array 13 to the absorption layer 7, and the far-infrared light emitted downward from the absorption layer 7 can be reflected by the reflective layer 6 to the absorption layer 7. With this arrangement, the waste of energy described above can be further suppressed and the sensitivity of the THz detection device can be further improved. Furthermore, the reflective layer 6 according to the present embodiment can suppress the THz wave incident on the absorption layer 7 from escaping from the lower surface of the absorption layer 7 to the outside of the absorption layer 7, which can further improve the sensitivity of the THz detection device.

Note that, because the absorption layer 7 according to the present embodiment receives the THz wave on the upper surface of the absorption layer 7, the reflective layer 6 of the present embodiment is provided not on the upper surface of the absorption layer 7 but on the lower surface of the absorption layer 7.

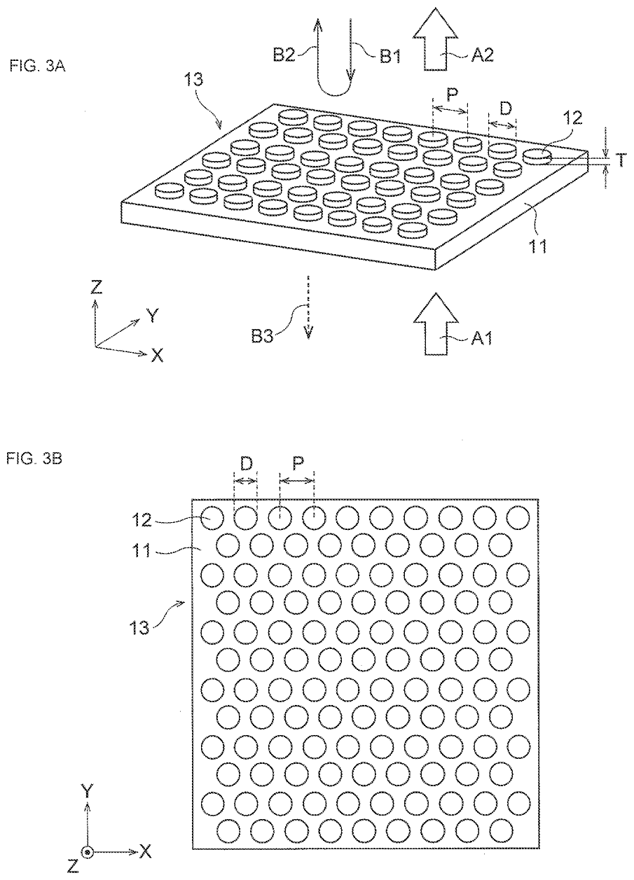

FIG. 3 is a perspective view and a plan view illustrating a structure of the structure array 13 according to the first embodiment.

A of FIG. 3 is a perspective view illustrating a structure of the structure array 13. However, in order to make the structure of the structure array 13 easy to see, the substrate 11 in A of FIG. 3 is illustrated in a direction opposite to the substrate 11 in FIG. 1. Therefore, the structure array 13 in FIG. 1 is provided on the lower surface of the substrate 11, whereas the structure array 13 in A of FIG. 3 is provided on the upper surface of the substrate 11. This applies similarly to B of FIG. 3. B of FIG. 3 is a plan view illustrating a structure of the structure array 13.

As illustrated in A and B of FIG. 3, the structure array 13 includes the plurality of structures 12 provided on the substrate 11, and these structures 12 are arranged in a two-dimensional array. These structures 12 are arranged in a triangular lattice layout in the present embodiment, but may be arranged in other layouts (for example, a square lattice).

In the present embodiment, each structure 12 has a cylindrical shape (A of FIG. 3). Therefore, each structure 12 has a circular shape in plan view (B of FIG. 3). However, each structure 12 may have other shapes. For example, the shape of each structure 12 in plan view may be a regular polygon.

Moreover, A and B of FIG. 3 illustrate a width D of each structure 12 in plan view, a pitch P between the structures 12 in plan view, and a thickness T of each structure 12. In a case where the shape of each structure 12 is a cylindrical shape, the width D indicates the diameter of each structure 12 in plan view.

As described above, the far-infrared light generated from the absorption layer 7 is incident on the structure array 13. The wavelength of this far-infrared light is, for example, about 10 μm. In this case, in order for the structure array 13 to reflect this far-infrared light, the width D is desirably larger than 10 μm, and the pitch P is desirably smaller than 10 μm. However, if the width D is excessively increased or the pitch P is excessively decreased, the far-infrared light is easily transmitted through the structure array 13. Therefore, the width D according to the present embodiment is set to, for example, 5 μm to 50 μm, preferably 5 μm to 25 μm. Similarly, the pitch P according to the present embodiment is set to, for example, 5 μm to 50 μm, preferably 5 μm to 25 μm.

Furthermore, the thickness T according to the present embodiment is desirably a value sufficient for the structure array 13 to reflect the far-infrared light. This value depends on, for example, the complex refractive index of the material forming each structure 12. The thickness T according to the present embodiment is set to, for example, 0.05 μm to 0.5 μm. With this arrangement, in a case where each structure 12 includes the metal as described above, the structure array 13 can suitably reflect the far-infrared light.

Note that the THz wave according to the present embodiment may pass through a gap between the structures 12 or may pass through each structure 12 when passing through the structure array 13.

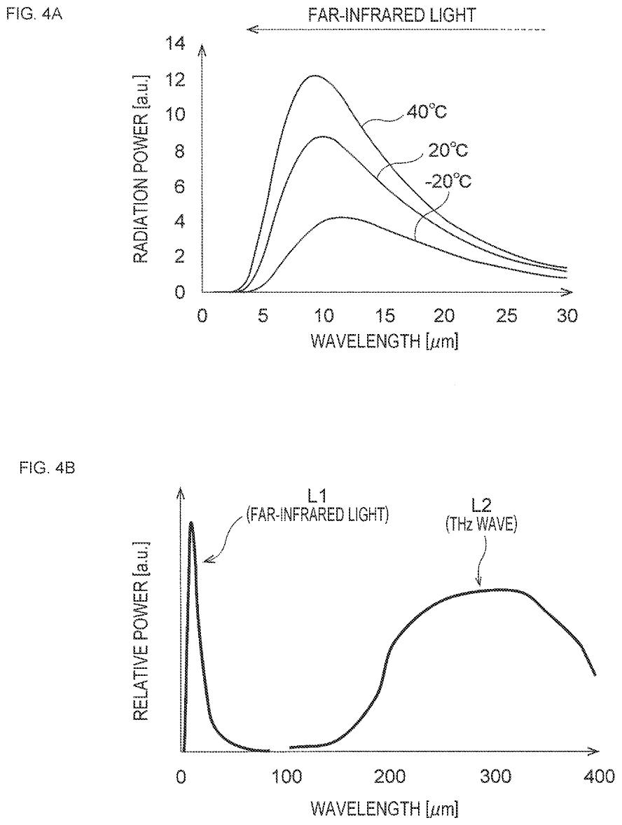

FIG. 4 is a graph for explaining characteristics of the THz detection device according to the first embodiment.

A of FIG. 4 illustrates a spectral distribution of an electromagnetic wave (far-infrared light) generated from the absorption layer 7 according to the present embodiment. A of FIG. 4 illustrates the relationship between a wavelength and radiation power of the electromagnetic wave generated from the absorption layer 7 at 40° C., 20° C., and −20° C. As can be seen from A of FIG. 4, a peak of the spectral distribution of the electromagnetic wave appears around 10 μm in these temperature zones.

A curve L1 illustrated in B of FIG. 4 is, similarly to A of FIG. 4, an example of a spectral distribution of an electromagnetic wave (far-infrared light) generated from the absorption layer 7 according to the present embodiment. Meanwhile, a curve L2 illustrated in B of FIG. 4 is an example of a spectral distribution of an electromagnetic wave (THz wave) incident on the absorption layer 7 according to the present embodiment. B of FIG. 4 illustrates the relationship between the wavelength and the relative power of these electromagnetic waves. In B of FIG. 4, the minimum wavelength of the THz wave is about 100 μm. In this case, the width D and the pitch P described above are desirably 50 μm or less, which is a half of 100 μm, and more desirably 25 μm or less.

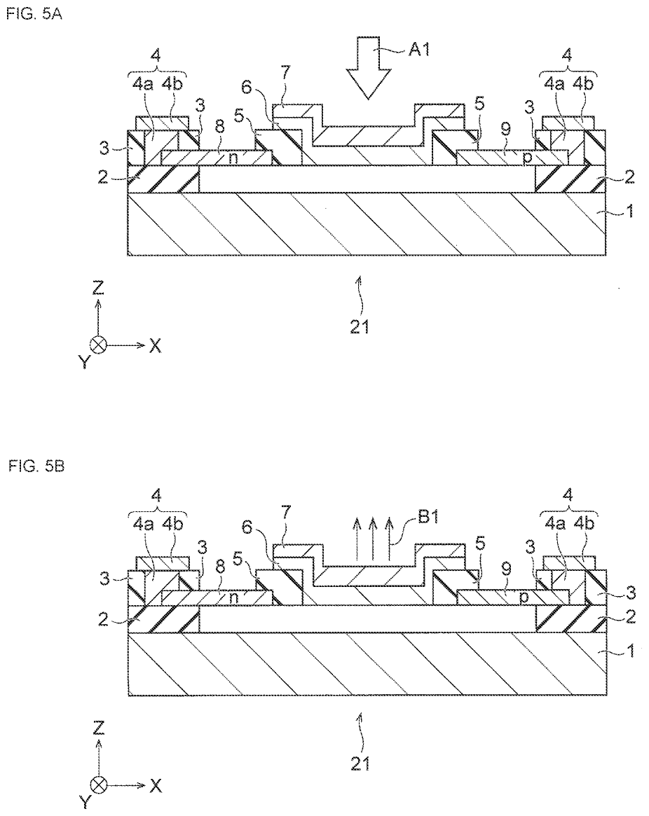

FIG. 5 is a cross-sectional view for describing a problem of the THz detection device according to a first comparative example of the first embodiment.

The THz detection device of the present comparative example has a structure in which the substrate 11, the structure 12, and the structure array 13 are removed from the THz detection device according to the first embodiment. A of FIG. 5 illustrates a state in which the THz wave is incident on the absorption layer 7. B of FIG. 5 illustrates a state in which the far-infrared light is generated from the absorption layer 7. Because the THz detection device of the present comparative example does not include a mechanism for returning the far-infrared light generated from the absorption layer 7 to the absorption layer 7 again, a part of the thermal energy generated in the absorption layer 7 is unnecessarily radiated to the outside of the absorption layer 7, and the sensitivity of the THz detection device decreases. On the other hand, according to the present embodiment, such a waste can be suppressed and the sensitivity of the THz detection device can be improved.

As described above, the THz detection device according to the present embodiment includes the structure array 13 including the plurality of structures 12 above the absorption layer 7. Therefore, according to the present embodiment, by causing the absorption layer 7 to absorb the far-infrared light generated from the absorption layer 7 again, the sensitivity for detecting the THz wave can be improved.

Note that the THz detection device of the present embodiment may detect electromagnetic waves other than THz while detecting the THz wave or instead of detecting the THz wave.

### Second Embodiment

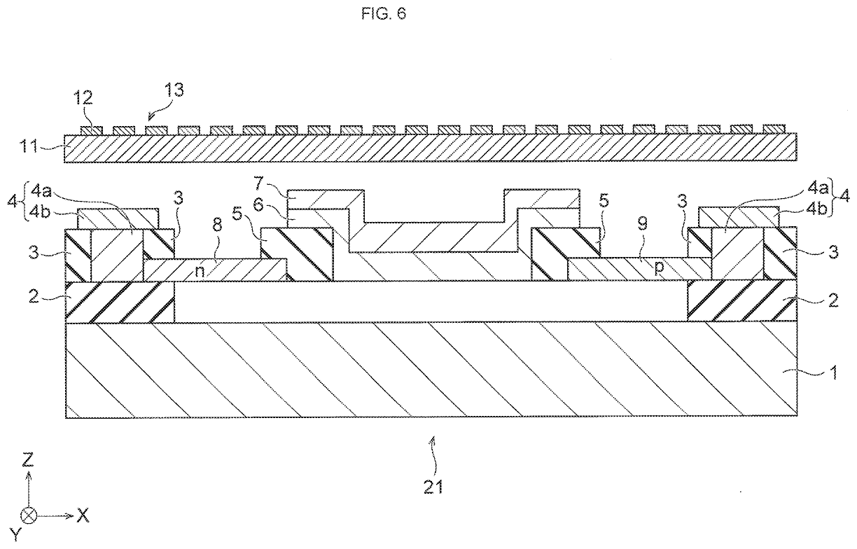

FIG. 6 is a cross-sectional view illustrating a structure of a THz detection device according to a second embodiment.

The THz detection device of the present embodiment includes similar constituents as those of the THz detection device according to the first embodiment. However, each structure 12 (a structure array 13) according to the present embodiment is provided on the upper surface of a substrate 11. According to the present embodiment, similarly to the first embodiment, the far-infrared light can be reflected by the structure array 13, and with this arrangement, the sensitivity for detecting the THz wave can be improved.

### Third Embodiment

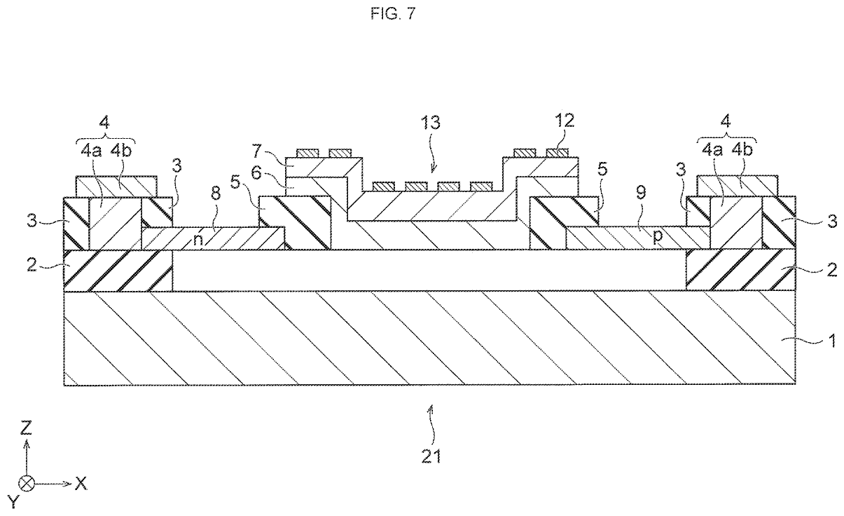

FIG. 7 is a cross-sectional view illustrating a structure of a THz detection device according to a third embodiment.

The THz detection device according to the present embodiment includes similar constituents as those of the THz detection device according to the first and second embodiments. However, each structure 12 (a structure array 13) according to the present embodiment is provided on the upper surface of an absorption layer 7 and is in contact with the absorption layer 7. According to the present embodiment, similarly to the first and second embodiments, the far-infrared light can be reflected by the structure array 13, and with this arrangement, the sensitivity for detecting the THz wave can be improved.

The structure array 13 according to the first and second embodiments is provided on the substrate 11 which is a member different from the absorption layer 7. Therefore, the far-infrared light generated from the absorption layer 7 propagates from the absorption layer 7 toward the substrate 11, is reflected by the structure array 13, propagates from the substrate 11 toward the absorption layer 7, and is absorbed by the absorption layer 7. In this case, there is a possibility that the far-infrared light dissipates in the propagation process between the absorption layer 7 and the substrate 11.

On the other hand, the structure array 13 according to the present embodiment is provided on the absorption layer 7. Therefore, the far-infrared light generated from the absorption layer 7 is reflected by the structure array 13 on the upper surface of the absorption layer 7 and absorbed by the absorption layer 7. With this arrangement, the dissipation of far-infrared light described above can be suppressed.

Note that, in a case where the structure array 13 is provided on the substrate 11, a degree of freedom of the layout of the structure array 13 is often higher than that in a case where the structure array 13 is provided on the absorption layer 7. The reason is that the absorption layer 7 has the step (side surface) between the inner upper surface and the outer upper surface, and the area of these upper surfaces is also smaller than the area of the upper surface and the lower surface of the substrate 11. Therefore, for example, in a case where use of such a degree of freedom is desired, the structure array 13 according to the first or second embodiment is desirably used.

Note that the THz detection device according to the present embodiment may include the substrate 11, the structure 12, and the structure array 13 of the first or second embodiment in addition to the constituents illustrated in FIG. 7. That is, the THz detection device of the present embodiment may include the structure array 13 on the upper surface of the absorption layer 7 and the structure array 13 on the upper surface or the lower surface of the substrate 11. With this arrangement, a larger amount of far-infrared light can be returned to the absorption layer 7. This similarly applies to fourth and fifth embodiments described later.

### Fourth Embodiment

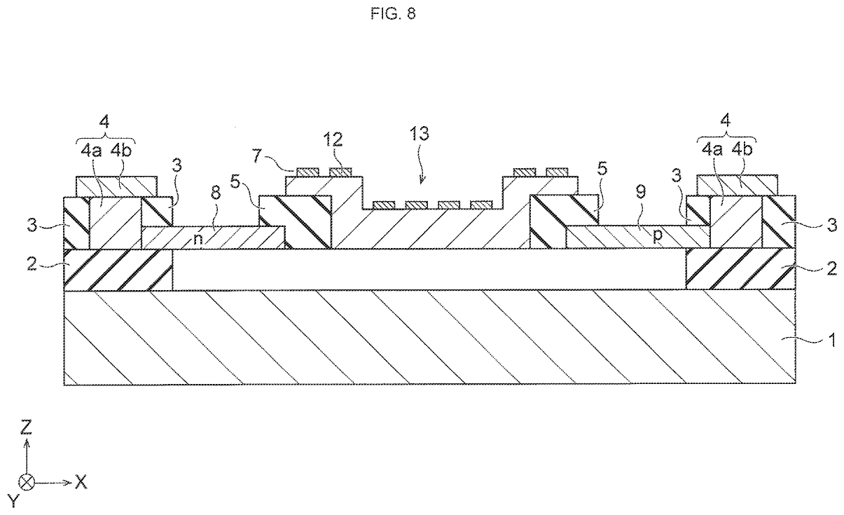

FIG. 8 is a cross-sectional view illustrating a structure of a THz detection device according to the fourth embodiment.

The THz detection device of the present embodiment has a structure in which the reflective layer 6 is removed from the THz detection device according to the third embodiment. That is, the THz detection device according to the present embodiment does not include a reflective layer 6 between an insulating film 5 and an absorption layer 7. The structure of the present embodiment can be adopted, for example, in a case where there is not much problem in the far-infrared light or the THz wave escaping from the lower surface of the absorption layer 7.

### Fifth Embodiment

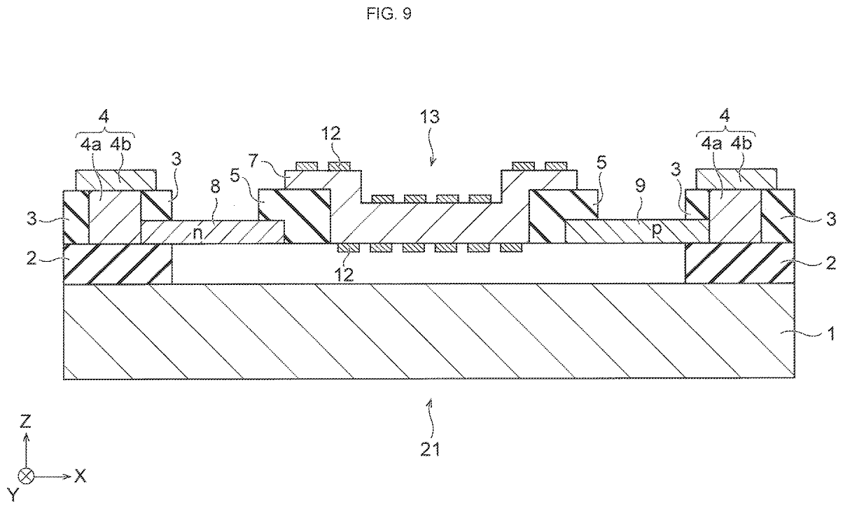

FIG. 9 is a cross-sectional view illustrating a structure of a THz detection device according to a fifth embodiment.

The THz detection device of the present embodiment includes similar constituents as those of the THz detection device according to the fourth embodiment. However, a structure array 13 according to the present embodiment is provided not only on the upper surface of an absorption layer 7, but also on the lower surface of the absorption layer 7. The THz detection device according to the present embodiment includes a plurality of structures 12 on the upper surface of the absorption layer 7, and the plurality of structures 12 on the lower surface of the absorption layer 7. According to the present embodiment, the far-infrared light can be reflected by the structure array 13 on the lower surface of the absorption layer 7 instead of the reflective layer 6, and with this arrangement, the sensitivity for detecting the THz wave can be improved.

Note that the width D, the pitch P, and the thickness T described in the first embodiment can also be applied to each of the structures 12 of the second to fifth embodiments. Furthermore, other matters described in the first embodiment with reference to FIG. 3 and the like can be applied to each of the structures 12 of the second to fifth embodiments.

### Comparison of First to Fifth Embodiments

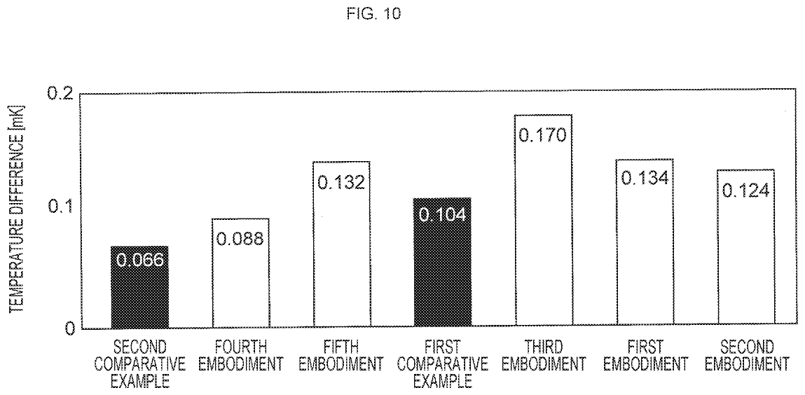

FIG. 10 is a graph for explaining characteristics of the THz detection devices according to the first to fifth embodiments and the like.

FIG. 10 illustrates simulation calculation results of temperature differences occurring at both ends of each thermoelectric element under the same condition in the THz detection devices of the first to fifth embodiments. Moreover, FIG. 10 illustrates simulation results of temperature differences occurring at both ends of each thermoelectric element under the above condition in a THz detection device of a first comparative example and a THz detection device of a second comparative example. As described above, the THz detection device of the first comparative example has a structure in which the substrate 11, the structure 12, and the structure array 13 are removed from the THz detection device according to the first embodiment (see FIG. 5). Meanwhile, the THz detection device of the second comparative example has a structure in which the structure 12 and the structure array 13 are removed from the THz detection device according to the fourth embodiment.

Therefore, the THz detection devices of the first to fifth embodiments include the structure array 13, but the THz detection devices of the first and second comparative examples do not include a structure array 13. Furthermore, the THz detection devices of the first to third embodiments and the first comparative example include the reflective layer 6, but the THz detection devices of the fourth and fifth embodiments and the second comparative example do not include the reflective layer 6. Note that the simulation calculation described above was performed under the condition that the structure array 13 transmits 100% of the THz wave and reflects 70% of the far-infrared light.

First, from the comparison between the first to third embodiments and the first comparative example, it can be seen that the temperature difference in a case where the THz detection device includes the reflective layer 6 and the structure array 13 is higher than the temperature difference in a case where the THz detection device includes only the reflective layer 6. Secondly, from the comparison between the fourth and fifth embodiments and the second comparative example, it can be seen that the temperature difference in a case where the THz detection device includes the structure array 13 is higher than the temperature difference in a case where the THz detection device does not include the structure array 13. From these results, it can be seen that the sensitivity to the THz wave in the THz detection device can be improved by the structure array 13.

### Application Example

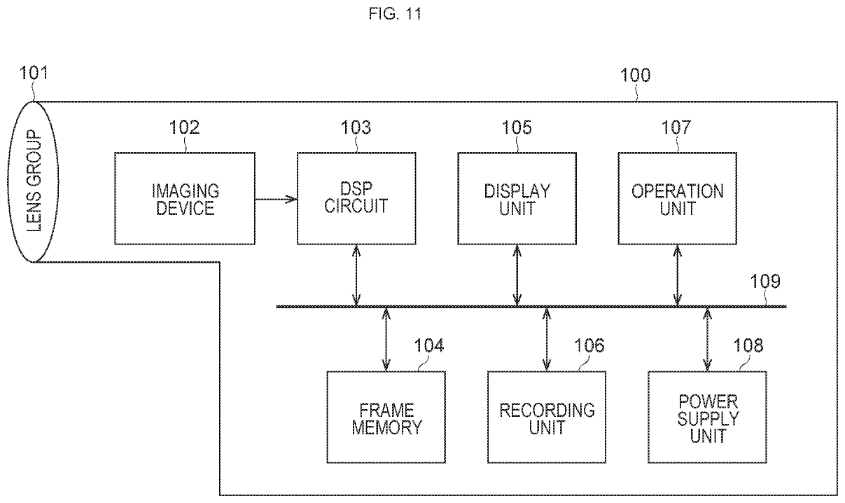

FIG. 11 is a block diagram illustrating a configuration example of an electronic device. The electronic device illustrated in FIG. 11 is a camera 100.

The camera 100 includes an optical unit 101 including a lens group and the like, an imaging device 102 that is the THz detection device according to any of the first to fifth embodiments, a digital signal processor (DSP) circuit 103 that is a camera signal processing circuit, a frame memory 104, a display unit 105, a recording unit 106, an operation unit 107, and a power supply unit 108. Furthermore, the DSP circuit 103, the frame memory 104, the display unit 105, the recording unit 106, the operation unit 107, and the power supply unit 108 are connected to each other via a bus line 109.

The optical unit 101 captures incident light (image light) from a subject and forms an image on an imaging surface of the imaging device 102. The imaging device 102 converts an amount of incident light formed into an image on the imaging surface by the optical unit 101 into an electric signal on a pixel-by-pixel basis and outputs the electric signal as a pixel signal.

The DSP circuit 103 performs signal processing on the pixel signal output from the imaging device 102. The frame memory 104 is a memory for storing one screen of a moving image or a still image captured by the imaging device 102.

The display unit 105 includes, for example, a panel type display device such as a liquid crystal panel or an organic EL panel, and displays a moving image or a still image captured by the imaging device 102. The recording unit 106 records a moving image or a still image captured by the imaging device 102 on a recording medium such as a hard disk or a semiconductor memory.

The operation unit 107 issues operation commands for various functions of the camera 100 in response to an operation performed by a user. The power supply unit 108 appropriately supplies various power supplies, which are operation power supplies for the DSP circuit 103, the frame memory 104, the display unit 105, the recording unit 106, and the operation unit 107, to these power supply targets.

By using the THz detection device according to any of the first to fifth embodiments as the imaging device 102, it can be expected that a satisfactory image is acquired.

The solid-state imaging device can be applied to various other products. For example, the solid-state imaging device may be mounted on any type of mobile bodies such as vehicles, electric vehicles, hybrid electric vehicles, motorcycles, bicycles, personal mobility, airplanes, drones, ships, and robots.

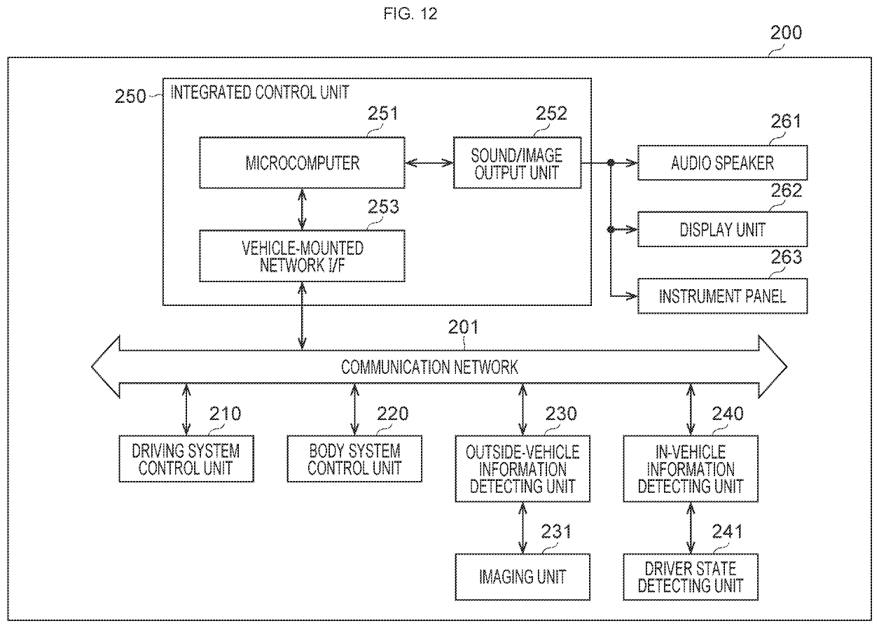

FIG. 12 is a block diagram illustrating a configuration example of a mobile body control system. The mobile body control system illustrated in FIG. 12 is a vehicle control system 200.

The vehicle control system 200 includes a plurality of electronic control units connected to each other via a communication network 201. In the example illustrated in FIG. 12, the vehicle control system 200 includes a driving system control unit 210, a body system control unit 220, an outside-vehicle information detecting unit 230, an in-vehicle information detecting unit 240, and an integrated control unit 250. Moreover, FIG. 12 illustrates a microcomputer 251, a sound/image output unit 252, and a vehicle-mounted network interface (I/F) 253 as components of the integrated control unit 250.

The driving system control unit 210 controls the operation of devices related to a driving system of a vehicle in accordance with various types of programs. For example, the driving system control unit 210 functions as a control device for a driving force generating device for generating a driving force of a vehicle, such as an internal combustion engine, a driving motor, or the like, a driving force transmitting mechanism for transmitting the driving force to wheels, a steering mechanism for adjusting a steering angle of the vehicle, a braking device for generating a braking force of the vehicle, and the like.

The body system control unit 220 controls the operation of various types of devices provided to a vehicle body in accordance with various types of programs. For example, the body system control unit 220 functions as a control device for a smart key system, a keyless entry system, a power window device, or various types of lamps (for example, a head lamp, a backup lamp, a brake lamp, a turn signal, a fog lamp, or the like). In this case, radio waves transmitted from a mobile device as an alternative to a key or signals of various types of switches can be input to the body system control unit 220. The body system control unit 220 receives inputs of such radio waves or signals, and controls a door lock device, the power window device, the lamps, or the like of the vehicle.

The outside-vehicle information detecting unit 230 detects information on the outside of the vehicle including the vehicle control system 200. The outside-vehicle information detecting unit 230 is connected with, for example, an imaging unit 231. The outside-vehicle information detecting unit 230 makes the imaging unit 231 capture an image of the outside of the vehicle, and receives the captured image from the imaging unit 231. On the basis of the received image, the outside-vehicle information detecting unit 230 may perform processing of detecting an object such as a human, an automobile, an obstacle, a sign, a character on a road surface, or the like, or processing of detecting a distance thereto.

The imaging unit 231 is an optical sensor that receives light and that outputs an electric signal corresponding to the amount of received light. The imaging unit 231 can output the electric signal as an image, or can output the electric signal as information on a measured distance. The light received by the imaging unit 231 may be visible light, or may be invisible light such as infrared light. The imaging unit 231 includes the THz detection device according to any of the first to fifth embodiments.

The in-vehicle information detecting unit 240 detects information on the inside of the vehicle equipped with the vehicle control system 200. The in-vehicle information detecting unit 240 is, for example, connected with a driver state detecting unit 241 that detects a state of a driver. For example, the driver state detecting unit 241 includes a camera that captures an image of the driver, and on the basis of detection information input from the driver state detecting unit 241, the in-vehicle information detecting unit 240 may calculate a degree of fatigue of the driver or a degree of concentration of the driver, or may determine whether or not the driver is dozing off. The camera may include the THz detection device according to any of the first to fifth embodiments, and may be, for example, the camera 100 illustrated in FIG. 11.

The microcomputer 251 can calculate a control target value for the driving force generating device, the steering mechanism, or the braking device on the basis of the information on the inside or outside of the vehicle obtained by the outside-vehicle information detecting unit 230 or the in-vehicle information detecting unit 240, and output a control command to the driving system control unit 210. For example, the microcomputer 251 can perform cooperative control intended to implement functions of an advanced driver assistance system (ADAS), the functions including collision avoidance or shock mitigation for the vehicle, following traveling based on a following distance, vehicle speed maintaining traveling, a warning of collision of the vehicle, a warning of deviation of the vehicle from a lane, and the like.

Furthermore, the microcomputer 251 can perform cooperative control intended for automated driving, which makes the vehicle travel autonomously without depending on the operation of the driver, or the like, by controlling the driving force generating device, the steering mechanism, the braking device, or the like on the basis of the information on the outside or inside of the vehicle obtained by the outside-vehicle information detecting unit 230 or the in-vehicle information detecting unit 240.

Furthermore, the microcomputer 251 can output a control command to the body system control unit 220 on the basis of the information on the outside of the vehicle obtained by the outside-vehicle information detecting unit 230. For example, the microcomputer 251 can perform cooperative control for the purpose of preventing glare, such as switching from a high beam to a low beam, by controlling the headlamp according to the position of a preceding vehicle or an oncoming vehicle detected by the outside-vehicle information detecting unit 230.

The sound/image output unit 252 transmits an output signal of at least one of a sound or an image to an output device that can visually or auditorily provide information to an occupant of the vehicle or the outside of the vehicle. In the example of FIG. 12, an audio speaker 261, a display unit 262, and an instrument panel 263 are illustrated as such an output device. The display unit 262 may, for example, include an on-board display or a head-up display.

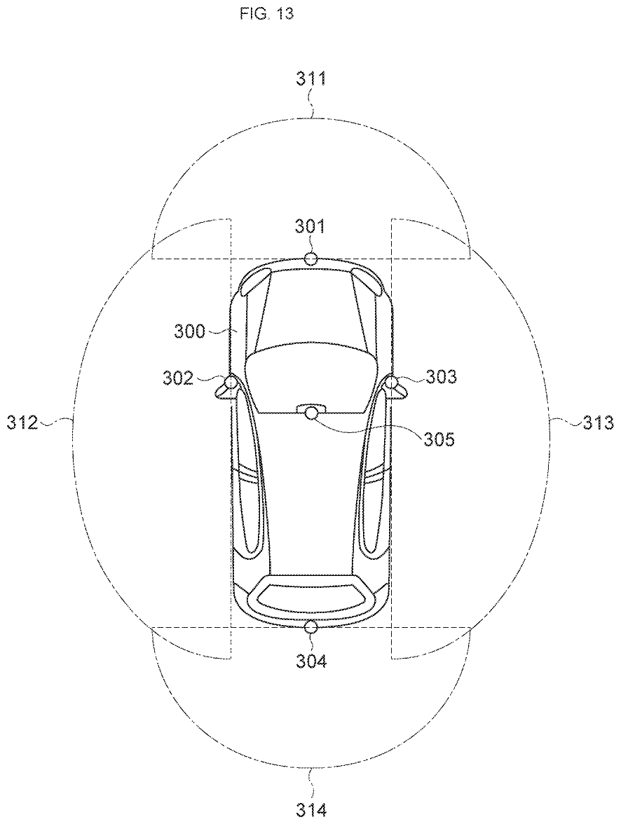

FIG. 13 is a plan view depicting a specific example of a setting position of the imaging unit 231 in FIG. 12.

A vehicle 300 illustrated in FIG. 13 includes imaging units 301, 302, 303, 304, and 305 as the imaging unit 231. The imaging units 301, 302, 303, 304, and 305 are, for example, provided at positions on a front nose, side mirrors, a rear bumper, and a back door of the vehicle 300, and on an upper portion of a windshield in the interior of the vehicle.

The imaging unit 301 provided on the front nose mainly acquires an image of the front of the vehicle 300. The imaging unit 302 provided on the left side mirror and the imaging unit 303 provided on the right side mirror mainly acquire images of the sides of the vehicle 300. The imaging unit 304 provided to the rear bumper or the back door mainly acquires an image of the rear of the vehicle 300. The imaging unit 305 provided to the upper portion of the windshield in the interior of the vehicle mainly acquires an image of the front of the vehicle 300. The imaging unit 305 is used to detect, for example, a preceding vehicle, a pedestrian, an obstacle, a signal, a traffic sign, a lane, and the like.

FIG. 13 illustrates an example of imaging ranges of the imaging units 301, 302, 303, and 304 (hereinafter referred to as “imaging units 301 to 304”). An imaging range 311 represents the imaging range of the imaging unit 301 provided to the front nose. An imaging range 312 represents the imaging range of the imaging unit 302 provided to the left side mirror. An imaging range 313 represents the imaging range of the imaging unit 303 provided to the right side mirror. An imaging range 314 represents the imaging range of the imaging unit 304 provided to the rear bumper or the back door. For example, an overhead view of the vehicle 300 as viewed from above is obtained by superimposing image data captured by the imaging units 301 to 304. Hereinafter, the imaging ranges 311, 312, 313, and 314 are referred to as the “imaging ranges 311 to 314”.

At least one of the imaging units 301 to 304 may have a function of acquiring distance information. For example, at least one of the imaging units 301 to 304 may be a stereo camera including a plurality of imaging devices or an imaging device including pixels for phase difference detection.

For example, the microcomputer 251 (FIG. 12) calculates a distance to each three-dimensional object within the imaging ranges 311 to 314 and a temporal change in the distance (relative speed with respect to the vehicle 300) on the basis of the distance information obtained from the imaging units 301 to 304. On the basis of the calculation results, the microcomputer 251 can extract, as a preceding vehicle, a nearest three-dimensional object that is present on a traveling path of the vehicle 300 and travels in substantially the same direction as the vehicle 300 at a predetermined speed (for example, equal to or more than 0 km/h). Moreover, the microcomputer 251 can set a following distance to be maintained in front of a preceding vehicle in advance, and perform automatic brake control (including following stop control), automatic acceleration control (including following start control), or the like. According to this example, the cooperative control intended for automated driving that makes the vehicle travel autonomously and the like can be performed without depending on the operation of the driver.

For example, the microcomputer 251 can classify three-dimensional object data related to three-dimensional objects into a two-wheeled vehicle, a standard-sized vehicle, a large-sized vehicle, a pedestrian, a utility pole, and other three-dimensional objects on the basis of the distance information obtained from the imaging units 301 to 304, extract the classified three-dimensional object data, and use the extracted three-dimensional object data for automatic avoidance of an obstacle. For example, the microcomputer 251 identifies obstacles around the vehicle 300 as obstacles that the driver of the vehicle 300 can recognize visually and obstacles that are difficult for the driver of the vehicle 300 to recognize visually. Then, the microcomputer 251 determines a collision risk indicating a risk of collision with each obstacle, and in a situation in which the collision risk is equal to or higher than a set value and there is thus a possibility of collision, the microcomputer 251 outputs a warning to the driver via the audio speaker 261 or the display unit 262, and performs forced deceleration or avoidance steering via the driving system control unit 210 to assist in driving to avoid collision.

At least one of the imaging units 301 to 304 may be an infrared camera that detects infrared light. The microcomputer 251 can, for example, recognize a pedestrian by determining whether or not there is a pedestrian in images captured by the imaging units 301 to 304. Such recognition of a pedestrian is, for example, performed by a procedure of extracting characteristic points in the images captured by the imaging units 301 to 304 as infrared cameras and a procedure of determining whether or not an object is a pedestrian by performing pattern matching processing on a series of characteristic points representing the contour of the object. In a case where the microcomputer 251 determines that there is a pedestrian in the captured images captured by the imaging units 301 to 304 and recognizes the pedestrian, the sound/image output unit 252 controls the display unit 262 so that a square contour line for emphasis is displayed in a superimposed manner on the recognized pedestrian. Furthermore, the sound/image output unit 252 may also control the display unit 262 so that an icon or the like representing the pedestrian is displayed at a desired position.

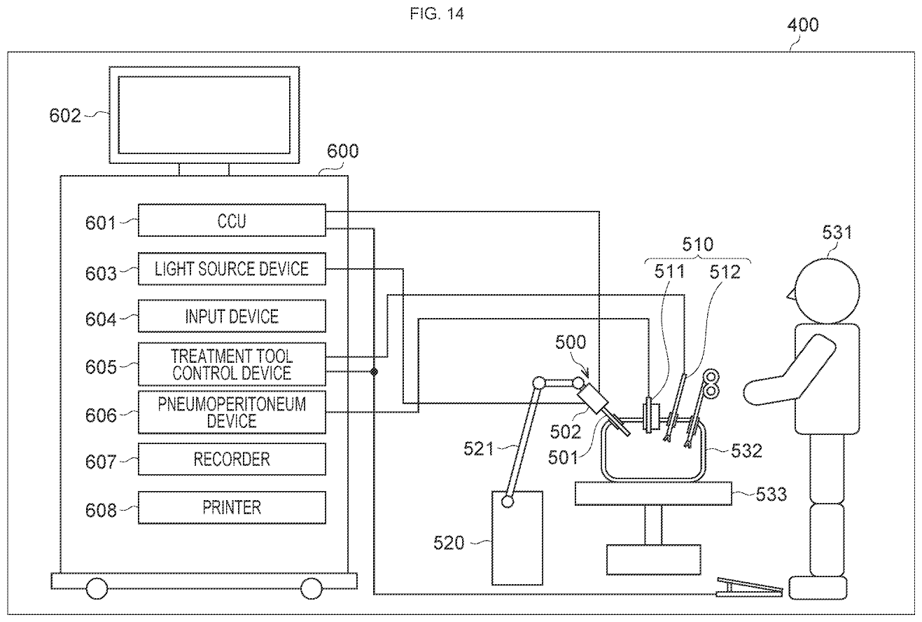

FIG. 14 is a diagram showing an example of a schematic configuration of an endoscopic surgery system to which the technology of the present disclosure (present technology) can be applied.

FIG. 14 illustrates a state in which a surgeon (medical doctor) 531 is using an endoscopic surgery system 400 to perform surgery for a patient 532 on a patient bed 533. As illustrated, the endoscopic surgery system 400 includes an endoscope 500, other surgical tools 510 such as a pneumoperitoneum tube 511 and an energy treatment tool 512, a supporting arm device 520 for supporting the endoscope 500, and a cart 600 on which various devices for endoscopic surgery are mounted.

The endoscope 500 includes a lens barrel 501 having a region of a predetermined length from a distal end thereof to be inserted into a body cavity of the patient 532, and a camera head 502 connected to a proximal end of the lens barrel 501. Although the illustrated example illustrates the endoscope 500 is configured as a so-called rigid endoscope having a rigid lens barrel 501, the endoscope 500 may be a so-called flexible endoscope having a flexible lens barrel.

An opening in which an objective lens is fitted is provided at the distal end of the lens barrel 501. A light source device 603 is connected to the endoscope 500, and light generated by the light source device 603 is guided to the distal end of the lens barrel by a light guide extending in the lens barrel 501 and is emitted to an observation target in the body cavity of the patient 532 through the objective lens. Note that the endoscope 500 may be a forward-viewing endoscope, an oblique-viewing endoscope, or a side-viewing endoscope.

An optical system and an imaging element are provided in the camera head 502, and light reflected by the observation target (observation light) is collected on the imaging element by the optical system. The imaging element photoelectrically converts the observation light and generates an electric signal corresponding to the observation light, that is, an image signal corresponding to an observation image. The image signal is transmitted to a camera control unit (CCU) 601 as RAW data.

The CCU 601 includes a central processing unit (CPU), a graphics processing unit (GPU), and the like, and integrally controls the operations of the endoscope 500 and a display device 602. Moreover, the CCU 601 receives the image signal from the camera head 502 and applies, on the image signal, various types of image processing, for example, development processing (demosaicing processing) or the like for displaying an image based on the image signal.

The display device 602 displays the image based on the image signal which has been subjected to the image processing by the CCU 601 under the control of the CCU 601.

The light source device 603 includes, for example, a light source such as a light emitting diode (LED), and supplies irradiation light for imaging a surgical site or the like to the endoscope 500.

An input device 604 is an input interface for the endoscopic surgery system 11000. A user may input various types of information and instructions to the endoscopic surgery system 400 via the input device 604. For example, the user inputs an instruction and the like to change an imaging condition (type of irradiation light, magnification, focal length and the like) by the endoscope 500.

A treatment tool control device 605 controls driving of the energy treatment tool 512 for tissue cauterization, incision, blood vessel sealing, and the like. A pneumoperitoneum device 606 sends gas into the body cavity of the patient 532 via the pneumoperitoneum tube 511 in order to inflate the body cavity for a purpose of securing a field of view by the endoscope 500 and securing work space for the operator. A recorder 607 is a device that can record various types of information regarding surgery. A printer 608 is a device that can print various types of information regarding surgery in various formats such as a text, an image, or a graph.

Note that, the light source device 603 which supplies the irradiation light for imaging the surgical site to the endoscope 500 may include, for example, an LED, a laser light source, or a white light source obtained by combining these. In a case where the white light source includes a combination of RGB laser light sources, because an output intensity and an output timing of each color (each wavelength) can be controlled with high accuracy, the light source device 603 can adjust white balance of a captured image. Furthermore, in this case, by irradiating the observation target with the laser light from each of the R, G, and B laser light sources in time division and controlling driving of the imaging element of the camera head 502 in synchronism with the irradiation timing, images corresponding to R, G, and B can be captured in time division. With this method, a color image can be obtained even if color filters are not provided to the imaging element.

Furthermore, the driving of the light source device 603 may be controlled such that the intensity of light to be output is changed every predetermined time. The driving of the imaging element of the camera head 502 is controlled in synchronization with a timing of changing the light intensity to obtain the images in time division, and the obtained images are synthesized to enable generation of an image with a high dynamic range that does not have so-called black defect and halation.

Furthermore, the light source device 603 may be able to supply light in a predetermined wavelength band adapted to special light observation. In the special light observation, for example, by emitting light in a narrower band than irradiation light (in other words, white light) at the time of normal observation using wavelength dependency of a body tissue to absorb light, so-called narrow band imaging is performed in which an image of a predetermined tissue, such as a blood vessel in a mucosal surface layer, is captured with high contrast. Alternatively, in the special light observation, fluorescent observation for obtaining an image from fluorescent light generated by irradiation of excitation light may be performed. In the fluorescence observation, a body tissue can be irradiated with excitation light to observe fluorescence from the body tissue (autofluorescence observation) or a reagent such as indocyanine green (ICG) is locally injected to a body tissue and irradiate the body tissue with excitation light corresponding to a fluorescent wavelength of the reagent to obtain a fluorescent image. The light source device 603 can be configured to supply narrow band light and/or excitation light adapted to such special light observation.

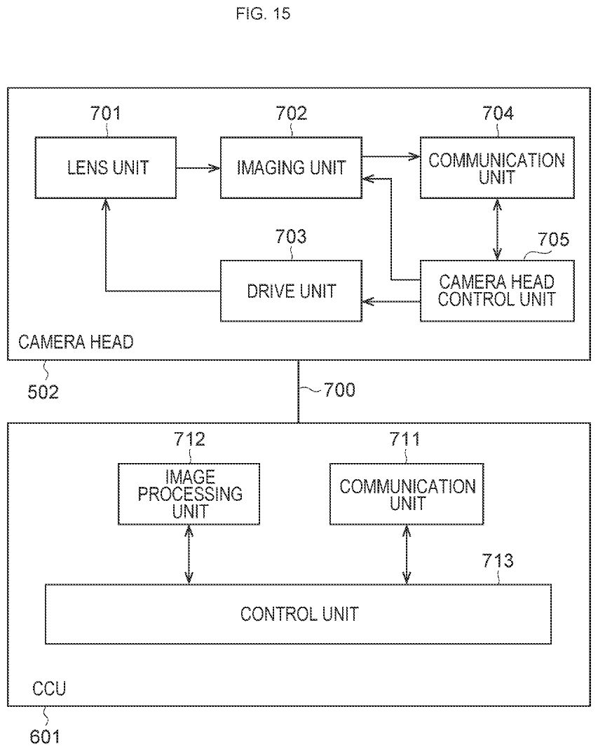

FIG. 15 is a block diagram illustrating an example of the functional configurations of the camera head 502 and the CCU 601 illustrated in FIG. 14.

The camera head 502 includes a lens unit 701, an imaging unit 702, a drive unit 703, a communication unit 704, and a camera head control unit 705. The CCU 601 includes a communication unit 711, an image processing unit 712, and a control unit 713. The camera head 502 and the CCU 601 are connected to each other communicably by a transmission cable 700.

The lens unit 701 is an optical system provided at a connection portion with the lens barrel 501. The observation light captured from the distal end of the lens barrel 501 is guided to the camera head 502 and enters the lens unit 701. The lens unit 701 is configured by combining a plurality of lenses including a zoom lens and a focus lens.

The imaging unit 702 includes an imaging element. The number of imaging elements included in the imaging unit 702 may be one (so-called single plate type) or two or more (so-called multiple plate type). In a case where the imaging unit 702 is configured as the multiple plate type, for example, image signals corresponding to R, G, and B may be generated by the respective imaging elements, and a color image may be obtained by combining the generated image signals. Alternatively, the imaging unit 702 may include a pair of imaging elements for obtaining right-eye and left-eye image signals corresponding to three-dimensional (3D) display. By performing the 3D display, the surgeon 531 can grasp a depth of a living body tissue in a surgical site more accurately. Note that, in a case where the imaging unit 702 is configured as the multiple plate type, a plurality of systems of lens units 701 may be provided so as to correspond to the respective imaging elements. The imaging unit 702 is, for example, the THz detection device according to any of the first to fifth embodiments.

Furthermore, the imaging unit 702 is not necessarily provided in the camera head 502. For example, the imaging unit 702 may be provided inside the lens barrel 501 immediately behind the objective lens.

The drive unit 703 includes an actuator and moves the zoom lens and the focusing lens of the lens unit 701 by a predetermined distance along an optical axis under the control of the camera head control unit 705. With this arrangement, the magnification and focal point of the image captured by the imaging unit 702 may be appropriately adjusted.

The communication unit 704 includes a communication device for transmitting and receiving various types of information to and from the CCU 601. The communication unit 704 transmits the image signal obtained from the imaging unit 702 as the RAW data to the CCU 601 via the transmission cable 700.

Furthermore, the communication unit 704 receives a control signal for controlling driving of the camera head 502 from the CCU 601 and supplies the control signal to the camera head control unit 705. The control signal includes, for example, the information regarding the imaging condition such as information specifying a frame rate of the captured image, information specifying an exposure value at the time of imaging, and/or information specifying the magnification and focus of the captured image.

Note that the imaging conditions such as the frame rate, exposure value, magnification, and focus described above may be appropriately specified by the user, or may be automatically set by the control unit 713 of the CCU 601 on the basis of the acquired image signal. In the latter case, the endoscope 500 is equipped with a so-called auto exposure (AE) function, an auto focus (AF) function, and an auto white balance (AWB) function.

The camera head control unit 705 controls the driving of the camera head 502 on the basis of the control signal from the CCU 601 received via the communication unit 704.

The communication unit 711 includes a communication device for transmitting and receiving various types of information to and from the camera head 502. The communication unit 711 receives the image signal transmitted from the camera head 502 via the transmission cable 700.

Furthermore, the communication unit 711 transmits the control signal for controlling the driving of the camera head 502 to the camera head 502. The image signal and the control signal can be transmitted by electrical communication, optical communication or the like.

The image processing unit 712 performs various types of image processing on the image signal which is the RAW data transmitted from the camera head 502.

The control unit 713 performs various types of control regarding imaging of the surgical site and the like by the endoscope 500 and display of the captured image obtained by the imaging of the surgical site and the like. For example, the control unit 713 generates the control signal for controlling the driving of the camera head 502.

Furthermore, the control unit 713 allows the display device 602 to display the captured image including the surgical site and the like on the basis of the image signal subjected to the image processing by the image processing unit 712. At this time, the control unit 713 may recognize various objects in the captured image using various image recognition technologies. For example, the control unit 713 may detect edge shapes, colors, and the like of the objects included in the captured image, to recognize the surgical tool such as forceps, a specific living body site, bleeding, mist when the energy treatment tool 512 is used, and the like. At the time of causing the display device 602 to display the captured image, the control unit 713 may overlay various types of surgery assistance information on the image of the surgical site using the recognition result. The surgery assistance information is displayed to be overlaid and presented to the surgeon 531, which can reduce the burden on the surgeon 531 and enable the surgeon 531 to reliably proceed with surgery.

The transmission cable 700 connecting the camera head 502 and the CCU 601 is an electric signal cable compatible with communication of electric signals, an optical fiber compatible with optical communication, or a composite cable thereof.

Here, in the illustrated example, the communication is performed wired using the transmission cable 700, but the communication between the camera head 502 and the CCU 601 may be performed wirelessly.

Although the embodiment of the present disclosure has been described above, the embodiment of the present disclosure may be implemented with various modifications without departing from the gist of the present disclosure. For example, two or more embodiments may be implemented in combination.

Note that the present disclosure can also have the following configurations.

(1)

A terahertz (THz) detection device including:
a structure array including a plurality of structures and transmitting a THz wave incident on the structures;
an absorption layer that absorbs the THz wave transmitted through the structure array and generates heat and far-infrared light; and
a thermoelectric element that converts the heat generated from the absorption layer into electricity, in which
the structure array reflects the far-infrared light generated from the absorption layer and incident on the structures, and
the absorption layer absorbs the far-infrared light reflected by the structure array.

(2)

The THz detection device according to (1), in which each of the structures includes a material in which a real part of a complex dielectric constant is negative.

(3)

The THz detection device according to (2), in which the material included in each of the structures is metal.

(4)

The THz detection device according to (1), in which each of the structures has a shape that is circular in plan view.

(5)

The THz detection device according to (1), in which each of the structures has a width of 5 μm to 25 μm in plan view.

(6)

The THz detection device according to (1), in which the structures have a pitch of 5 μm to 25 μm in plan view between the structures.

(7)

The THz detection device according to (1), in which each of the structures has a thickness of 0.05 μm to 0.5 μm.

(8)

The THz detection device according to (1), in which the structures are arranged in a two-dimensional array.

(9)

The THz detection device according to (1), in which each of the structures is provided at a position away from the absorption layer.

(10)

The THz detection device according to (1), in which each of the structures is provided at a position in contact with the absorption layer.

(11)

The THz detection device according to (1), in which each of the structures is provided on a lower surface of a substrate positioned above the absorption layer.

(12)

The THz detection device according to (1), in which each of the structures is provided on an upper surface of a substrate positioned above the absorption layer.

(13)

The THz detection device according to (1), in which each of the structures is provided on an upper surface of the absorption layer.

(14)

The THz detection device according to (1), in which each of the structures is provided on a lower surface of the absorption layer.

(15)

The THz detection device according to (1), further including a reflective layer that is provided on a lower surface of the absorption layer and reflects the far-infrared light generated from the absorption layer to the absorption layer.

(16)

The THz detection device according to (15), in which the reflective layer includes a metal layer.

(17)

The THz detection device according to (1), in which the absorption layer includes carbon.

(18)

The THz detection device according to (17), in which the absorption layer includes a carbon nanotube, graphene, or graphite.

(19)

The THz detection device according to (1), in which the thermoelectric element includes one or more n-type semiconductor layers and one or more p-type semiconductor layers electrically insulated from the absorption layer.

(20)

The THz detection device according to (19), in which the one or more n-type semiconductor layers and the one or more p-type semiconductor layers are electrically connected to each other in series.

### REFERENCE SIGNS LIST

1 Substrate
2 Lower insulating film
3 Upper insulating film
4 Wiring line
4 a Lower wiring layer
4b Upper wiring layer
5 Insulating film
6 Reflective layer
7 Light absorption layer
8 n-type semiconductor layer (thermoelectric element)
9 p-type semiconductor layer (thermoelectric element)
10 Wiring line
11 Substrate
12 Structure
13 Structure array
21 Pixel
22 Pixel array

1. A terahertz (THz) detection device comprising:
a structure array including a plurality of structures and transmitting a THz wave incident on the structures;
an absorption layer that absorbs the THz wave transmitted through the structure array and generates heat and far-infrared light; and
a thermoelectric element that converts the heat generated from the absorption layer into electricity, wherein
the structure array reflects the far-infrared light generated from the absorption layer and incident on the structures, and
the absorption layer absorbs the far-infrared light reflected by the structure array.

2. The THz detection device according to claim 1, wherein each of the structures includes a material in which a real part of a complex dielectric constant is negative.

3. The THz detection device according to claim 2, wherein the material included in each of the structures is metal.

4. The THz detection device according to claim 1, wherein each of the structures has a shape that is circular in plan view.

5. The THz detection device according to claim 1, wherein each of the structures has a width of 5 μm to 25 μm in plan view.

6. The THz detection device according to claim 1, wherein the structures have a pitch of 5 μm to 25 μm in plan view between the structures.

7. The THz detection device according to claim 1, wherein each of the structures has a thickness of 0.05 μm to 0.5 μm.

8. The THz detection device according to claim 1, wherein the structures are arranged in a two-dimensional array.

9. The THz detection device according to claim 1, wherein each of the structures is provided at a position away from the absorption layer.

10. The THz detection device according to claim 1, wherein each of the structures is provided at a position in contact with the absorption layer.

11. The THz detection device according to claim 1, wherein each of the structures is provided on a lower surface of a substrate positioned above the absorption layer.

12. The THz detection device according to claim 1, wherein each of the structures is provided on an upper surface of a substrate positioned above the absorption layer.

13. The THz detection device according to claim 1, wherein each of the structures is provided on an upper surface of the absorption layer.

14. The THz detection device according to claim 1, wherein each of the structures is provided on a lower surface of the absorption layer.

15. The THz detection device according to claim 1, further comprising a reflective layer that is provided on a lower surface of the absorption layer and reflects the far-infrared light generated from the absorption layer to the absorption layer.

16. The THz detection device according to claim 15, wherein the reflective layer includes a metal layer.

17. The THz detection device according to claim 1, wherein the absorption layer includes carbon.

18. The THz detection device according to claim 17, wherein the absorption layer includes a carbon nanotube, graphene, or graphite.

19. The THz detection device according to claim 1, wherein the thermoelectric element includes one or more n-type semiconductor layers and one or more p-type semiconductor layers electrically insulated from the absorption layer.

20. The THz detection device according to claim 19, wherein the one or more n-type semiconductor layers and the one or more p-type semiconductor layers are electrically connected to each other in series.
